(19) United States
(12) Patent Application Publication
(10) Pub. No.: US 2025/0105132 A1
(43) Pub. Date: Mar. 27, 2025

(54) POROUS COPPER LINER FOR THROUGH GLASS VIA (TGV) GLASS CORES

(71) Applicant: Intel Corporation, Santa Clara, CA (US)

(72) Inventors: Pratyush MISHRA, Tempe, AZ (US); Pratyasha MOHAPATRA, Hillsboro, OR (US); Srinivas Venkata Ramanuja PIETAMBARAM, Chandler, AZ (US)

(21) Appl. No.: 18/373,095

(22) Filed: Sep. 26, 2023

(51) Int. Cl. H01L 23/498; H01L 23/15; H05K 1/02; H05K 1/03; H05K 1/09; H05K 1/11

(52) U.S. Cl. CPC H01L 23/49894; H01L 23/15; H01L 23/49827; H05K 1/0271; H05K 1/0306; H05K 1/095; H05K 1/116

(57) ABSTRACT

Embodiments disclosed herein include glass cores with through glass vias (TGVs). In an embodiment, an apparatus comprises a substrate that is a solid glass layer, and an opening through a thickness of the substrate. In an embodiment, a via structure is in the opening, where the via structure comprises a first region with an electrically conductive material with a first porosity, and a second region in contact with the first region, where the second region comprises an electrically conductive material with a second porosity that is less than the first porosity. In an embodiment, the second region is separated from a sidewall of the opening by the first region.

### BACKGROUND

As semiconductor packaging architectures continue towards more complex and more compact systems, new material solutions may be used to enable such architectures. One promising candidate for use in packaging substrates is a glass core layer. In such substrates, a glass core is sandwiched between overlying and underlying buildup layers. Electrically conductive vias are provided through the glass core in order to provide electrical coupling between the overlying and underlying buildup layers. Glass cores are beneficial because they can provide high density vias. Glass is also a high modulus material, which provides desirable stiffness to the overall package substrate.

However, coefficient of thermal expansion (CTE) mismatch between the glass core and the via can lead to damage during high temperature operations, such as annealing. Further, high elastic moduli for copper in the via and the glass core can lead to a reduction in the glass core failure strength. Stated another way, the expanding copper pushes against the glass, and since both materials are stiff, elastic deformation is reduced and cracks can occur. This reduction in failure strength can lead to glass failure and breaking in subsequent processing operations.

### BRIEF DESCRIPTION OF THE DRAWINGS

FIG. 1A is a cross-sectional illustration of a glass core with a buffer layer around the via, in accordance with an embodiment.

FIG. 1B is a cross-sectional illustration of the glass core showing the porosity of the buffer layer being higher than the porosity of the via, in accordance with an embodiment.

FIG. 2A is a cross-sectional illustration of a glass core with a buffer layer plated up from a seed layer and a via inside the buffer layer, in accordance with an embodiment.

FIG. 2B is a cross-sectional illustration of the glass core showing the porosity of the buffer layer over the seed layer, in accordance with an embodiment.

FIG. 3A is a cross-sectional illustration of a glass core with a liner and a buffer layer around a via, in accordance with an embodiment.

FIG. 3B is a cross-sectional illustration of the glass core with a liner between the buffer layer and the glass core, in accordance with an embodiment.

FIGS. 4A-4F are cross-sectional illustrations depicting a process for forming a via through a glass core that includes a high porosity buffer layer deposited with a chemical vapor deposition (CVD) or physical vapor deposition (PVD) process, in accordance with an embodiment.

FIGS. 5A-5F are cross-sectional illustrations depicting a process for forming a via through a glass core that includes a high porosity buffer layer deposited with an electroplating process, in accordance with an embodiment.

FIGS. 6A-6F are cross-sectional illustrations depicting a process for forming a via through a glass core that includes a high porosity buffer layer over a liner, in accordance with an embodiment.

FIG. 7 is a cross-sectional illustration of a package substrate with a glass core that includes a via and a high porosity buffer layer, in accordance with an embodiment.

FIG. 8 is a cross-sectional illustration of an electronic system that includes a package substrate with a glass core that includes a via and a high porosity buffer layer, in accordance with an embodiment.

FIG. 9 is a schematic of a computing device built in accordance with an embodiment.

### EMBODIMENTS OF THE PRESENT DISCLOSURE

Described herein are electronic systems, and more particularly, glass cores with via structures that include a high porosity buffer layer and a nonporous via surrounded by the buffer layer, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

As noted above, coefficient of thermal expansion (CTE) mismatch and high elastic moduli between the conductive via and the glass core are capable of generating significant damage to the glass core, especially during annealing processes. One solution proposed to combat these material compatibility issues is the use of a compressible liner between the glass core and the conductive via. However, the placement of the liner materials along the via opening reduces the real estate available for the plated copper. This reduces the conductive path diameter in the case of electrically insulating liners. In the case of conductive liners (e.g., aluminum liners), the conductivity is reduced compared to traditional via materials, such as copper. To mitigate the reduction in electrical performance, lower aspect ratio vias may be used to account for the liner footprint.

Further, the introduction of different liner materials results in additional processing operations. This can impact the processing costs, time, throughput, and the like. Additional liner layers also increase the number of processing operations, which leads to more complex manufacturing flows.

Liner architectures may also be limited due to poor adhesion to the glass material. For example, polymeric liners are susceptible to detachment from the glass core due to the low tensile strength of most polymers. During annealing cycles, the expansion followed by the contraction of copper can cause the organic liner to detach from the sidewall of the via opening through the glass core. As such, architectures with liners face additional reliability considerations.

Accordingly, embodiments disclosed herein utilize a buffer layer in order to accommodate the stresses induced by the CTE mismatch between the via and the glass core. The buffer layer may be a ring that surrounds the via. The buffer layer may be directly on the glass, the buffer layer may be separated from the glass by a seed layer, or the buffer layer may be provided over a liner. Generally, the buffer layer has an elastic modulus that is lower than the elastic modulus of the via. This allows for elastic deformation within the buffer layer in order to accommodate the expansion of the via during high temperature operations, such as annealing.

In an embodiment, the lower elastic modulus of the buffer layer is provided without a significant decrease in the electrical conductivity of the buffer layer. This may be obtained by using the same (or substantially the same) material composition for the via and the buffer layer while modifying the microstructure of the two regions. For example, a porosity of the buffer layer may be higher than a porosity of the via. In one embodiment, the via may have substantially no porosity, and the buffer layer may have up to approximately 60% porosity.

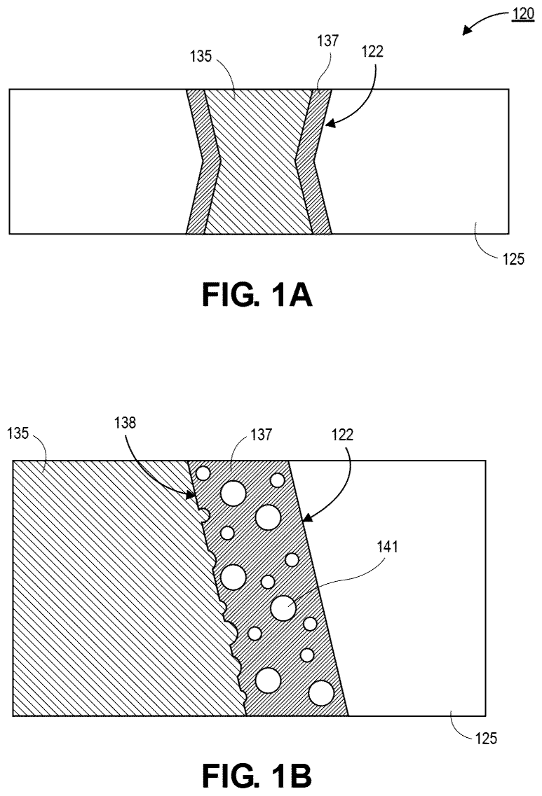

Referring now to FIG. 1A, a cross-sectional illustration of a glass core 120 is shown, in accordance with an embodiment. In an embodiment, the glass core 120 may comprise a glass layer 125. The glass layer 125 may be substantially all glass. That is, the glass layer 125 is distinct from a traditional organic core layer that may have glass fiber reinforcement. The glass layer 125 may be a solid material with an amorphous crystal structure. More particularly, the glass layer 125 may be any suitable glass formulation that has the necessary mechanical robustness and compatibility with semiconductor packaging manufacturing and assembly processes. For example, the glass layer 125 may comprise aluminosilicate glass, borosilicate glass, alumino-borosilicate glass, silica, fused silica, or the like. In some embodiments, the glass layer 125 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, and Zn. More generally, the glass layer 125 may comprise silicon and oxygen, as well as any one or more of aluminum, boron, magnesium, calcium, barium, tin, sodium, potassium, strontium, phosphorus, zirconium, lithium, titanium, and zinc. In an embodiment, the glass layer 125 may comprise at least 23 percent silicon (by weight) and at least 26 percent oxygen (by weight). In some embodiments, the glass layer 125 may further comprise at least 5 percent aluminum (by weight).

In an embodiment, the glass layer 125 may have a thickness that is between approximately 50 μm and approximately 2,000 μm. Though, thinner or thicker glass layers 125 may be used in some embodiments. As used herein, “approximately” may refer to a range of values that are within ten percent of the stated layer. For example, approximately 100 μm may refer to a range between 90 μm and 110 μm. In an embodiment, the glass layer 125 may have a rectangular shape (when viewed from above in a plan view). Though, the glass layer 125 may have other shapes as well.

In an embodiment, an opening may pass through a thickness of the glass layer 125. Sidewalls 122 may define the opening. In the illustrated embodiment, the sidewalls 122 are sloped or tapered. Particularly, the sidewalls 122 in FIG. 1A depict an opening with an hourglass shaped cross-section. Such a shape is typical of double sided laser assisted etching processes. In the case of a single sided process, the sidewalls 122 may have a single taper, so that the top of the opening is wider than a bottom of the opening. Of course, embodiments may also include sidewalls 122 that have any amount of slope (or substantially no slope), depending on the processing operations used to form the opening through the glass layer 125.

In an embodiment, the opening through the glass layer 125 may be a high aspect ratio feature. As used herein, high aspect ratio features may refer to features that have an aspect ratio (height: width) that is approximately 5:1 or greater, approximately 10:1 or greater, or approximately 20:1 or greater. In some embodiments, a maximum width of the opening through the glass layer 125 may be up to approximately 200 μm. For example, the maximum width of the opening may be between approximately 25 μm and approximately 150 μm.

In an embodiment, a via 135 may at least partially fill the opening through the glass layer 125. The via 135 may be an electrically conductive material. For example, the via 135 may comprise copper or an alloy including copper. The via 135 may also include other electrically conductive metallic elements as well. In an embodiment, the via 135 may have a porosity that allows for excellent electrical performance. For example, the via 135 may be up to approximately 10% porous. Though, in some embodiments, the the via 135 may be approximately 0% porous or nonporous.

In an embodiment, the via 135 may be separated from the glass layer 125 by a buffer layer 137. In the illustrated embodiment, the buffer layer 137 is directly contacting the glass layer 125. That is, there may not be a seed layer or the like between the buffer layer 137 and the glass layer 125. Such an embodiment is obtainable using chemical vapor deposition (CVD) or physical vapor deposition (PVD) processes in order to deposit the buffer layer 137. The buffer layer 137 may have a thickness that is up to approximately 30 μm. For example, the buffer layer 137 may have a thickness that is between approximately 5 μm and approximately 20 μm.

In an embodiment, the buffer layer 137 may be an electrically conductive material. For example the buffer layer 137 may comprise copper, an alloy of copper, or the like. In a particular embodiment, the buffer layer 137 includes the same (or substantially the same) material composition as the via 135.

In an embodiment, the buffer layer 137 has an elastic modulus that is lower than the elastic modulus of the via 135, even in cases when the buffer layer 137 is the same material as the via 135. This is made possible by depositing a buffer layer 137 that includes a porosity that is higher than the porosity of the via 135. For example, the buffer layer 137 may have a structure with up to approximately 60% porosity. Increasing the porosity of the buffer layer 137 can have a significant impact on elastic modulus. For example, at approximately 40% porosity, copper has an elastic modulus of approximately 35 GPa, compared to an elastic modulus of approximately 130 GPa for non-porous copper. A decrease in the elastic modulus of the buffer layer 137 next to the glass layer 125 leads to lower stress generation in the glass core during high temperature processes, such as annealing. As such, reductions in the failure strength of the glass layer 125 are lowered or eliminated.

Despite the lower elastic modulus, the buffer layer 137 still retains a suitably high electrical conductivity. That is, the material composition (e.g., copper) of the buffer layer 137 allows for high electrical conductivity. In an embodiment, the electrical conductivity of the buffer layer 137 may be up to approximately 75% of that of the via 135, up to approximately 90% of that of the via 135, or up to approximately 99% of that of the via 135. Accordingly, occupying space in the opening of the glass core 125 does not significantly impact the electrical performance of the via structure. As such, high aspect ratio vias are still possible when using such architectures.

Referring now to FIG. 1B, a zoomed in illustration of the interface between layers adjacent to the sidewall 122 of the opening through the glass layer 125 is shown, in accordance with an embodiment. As shown, the buffer layer 137 conforms to the slope of the sidewall 122, and the buffer layer 137 is in direct contact with the glass layer 125. The buffer layer 137 may be characterized as having a porous microstructure. Particularly, there may be voids 141 distributed throughout the volume of the buffer layer 137. The voids 141 may be provided as a result of the processing conditions used to deposit the buffer layer 137. In the illustrated embodiment, the voids 141 are shown as being substantially circular. Though, voids 141 may take any shape.

In the illustrated embodiment, the porosity of the buffer layer 137 is substantially constant across the thickness of the buffer layer 137. However, in other embodiments, the porosity may vary across the thickness of the buffer layer 137. For example, a portion of the buffer layer 137 proximate to the glass layer 125 may have a porosity that is higher than a porosity of a portion of the buffer layer 137 proximate to the via 135. The porosity may change linearly across the thickness of the buffer layer 137. Though, embodiments may include any porosity distribution across the thickness of the buffer layer 137.

In an embodiment, the via 135 is in direct contact with the buffer layer 137. The via 135 and the buffer layer 137 may form a seam or interface 138 that is visible in some instances. The interface 138 may be substantially linear in some embodiments. Though, in some cases the buffer layer 137 has a non-linear surface due to the porosity. In instances such as these, the via 135 may conform to the shape of the buffer layer 137, and the interface 138 may be nonlinear. For example, the buffer layer 137 may have cavities or craters along the interface 138 between the buffer layer 137 and the via 135.

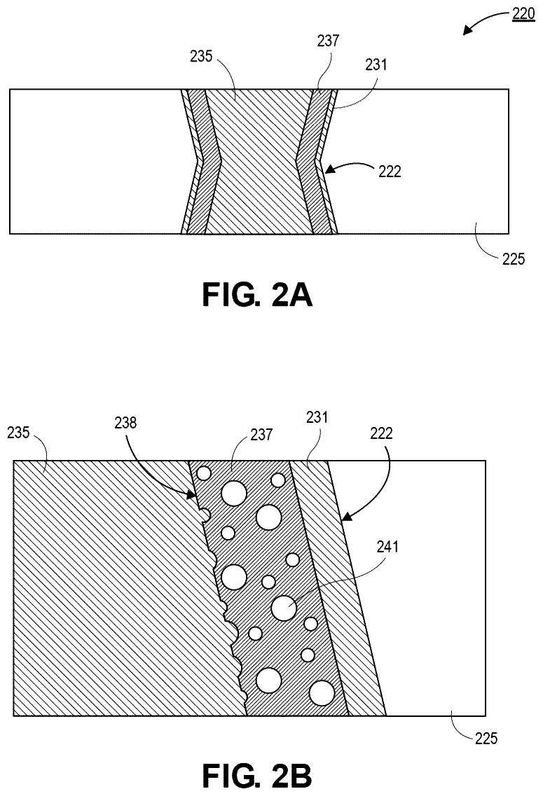

Referring now to FIG. 2A, a cross-sectional illustration of a glass core 220 is shown, in accordance with an additional embodiment. In an embodiment, the glass core 220 includes a glass layer 225. The glass layer 225 may be similar to any of the glass layers described in greater detail herein. The glass layer 225 may have an opening that passes through a thickness of the glass layer 225. Sidewalls 222 may define the outer edges of the opening.

In an embodiment, a via structure is provided in the opening. The via structure may comprise a via 235, a buffer layer 237, and a seed layer 231. The seed layer 231 may be provided between the buffer layer 237 and the glass layer 225. The buffer layer 237 may be a ring that surrounds the via 235. In an embodiment, the via 235 may be similar to the via 135 described in greater detail above. The buffer layer 237 may be similar to the buffer layer 137 described in greater detail above, except for the process used to deposit the buffer layer 137. Instead of CVD or PVD processes, the buffer layer 237 may be deposited with a plating process, such as an electroplating process. That is, the buffer layer 237 may be plated up from the seed layer 231. Further, the via 235 may also be electroplated. As such, the buffer layer 237 and the via 235 may be plated in a single plating bath. In order to provide the porosity differences between the buffer layer 237 and the via 235, different plating parameters may be used, as will be described in greater detail below.

Referring now to FIG. 2B, a zoomed in cross-sectional illustration of the interface between layers adjacent to the sidewall 222 of the opening through the glass layer 225 is shown, in accordance with an embodiment. As shown, the seed layer 231 may be provided in direct contact with the glass layer 225. That is, the seed layer 231 separates the buffer layer 237 from the glass layer 225. The seed layer 231 may have a thickness that is between approximately 5 nm and approximately 5 μm. Though, thinner or thicker seed layers 231 may be used in some embodiments.

In an embodiment, the seed layer 231 has a porosity that is lower than a porosity of the buffer layer 237. For example, the seed layer 231 may have up to approximately 20% porosity in some embodiments. The porosity of the seed layer 231 may be the same (or similar) to the porosity of the via 235 in some embodiments. The seed layer 231 may comprise copper in some embodiments. The seed layer 231 may also comprise catalytic elements, such as palladium or the like.

In an embodiment, the via 235 is in direct contact with the buffer layer 237. The via 235 and the buffer layer 237 may form a seam or interface 238 that is visible in some instances. The interface 238 may be substantially similar to the interface 138 described in greater detail above. In an embodiment, the buffer layer 237 may include voids 241 or the like.

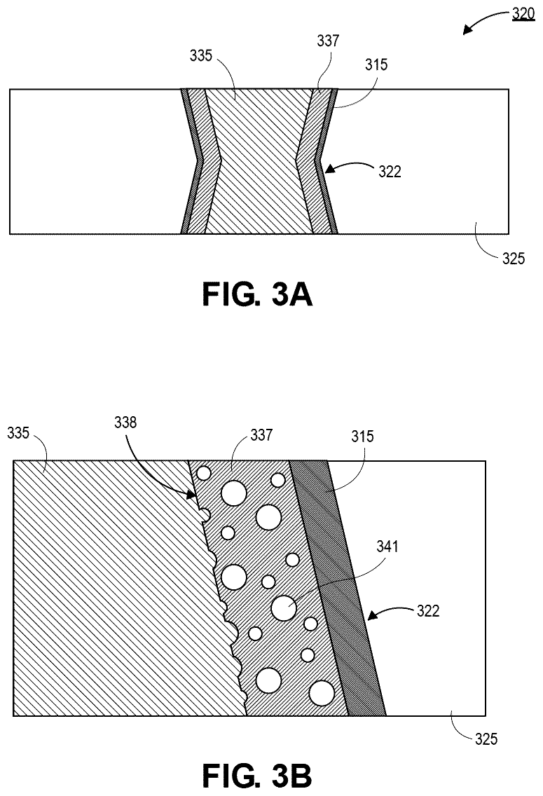

Referring now to FIG. 3A, a cross-sectional illustration of a glass core 320 is shown, in accordance with an embodiment. In an embodiment, the glass core 320 includes a glass layer 325. The glass layer 325 may be similar to any of the glass layers described in greater detail herein. The glass layer 325 may have an opening that passes through a thickness of the glass layer 325. Sidewalls 322 may define the outer edges of the opening.

In an embodiment, the glass core 320 may comprise a via structure in the opening. The via structure may comprise a via 335, a buffer layer 337, and a liner 315. The liner 315 may be in direct contact with the glass layer 325. The buffer layer 337 may be applied directly over the liner 315. For example, a CVD or PVD process may be used to deposit the buffer layer 337 over the liner 315. In other embodiments, a seed layer (not shown) may be provided between the buffer layer 337 and the liner 315. In such instances, an electroplating process may be used to deposit the buffer layer 337.

In an embodiment, the liner 315 may be a low elastic modulus material in order to further reduce stress application to the glass layer 325 during high temperature processes, such as annealing. In an embodiment, the liner 315 may be a polymeric material. For example, the liner 315 may comprise parylene or the like.

The buffer layer 337 may be a ring that surrounds an outer perimeter of the via 335. The buffer layer 337 and the via 335 may be substantially similar to any of the buffer layers or vias described in greater detail herein. For example, the buffer layer 337 and the via 335 may have different porosities. For example, the buffer layer 337 may have a porosity up to approximately 60% and the via 335 may be substantially nonporous or have a porosity up to approximately 10%.

Referring now to FIG. 3B, a zoomed in cross-sectional illustration of the interface between layers adjacent to the sidewall 322 of the opening through the glass layer 325 is shown, in accordance with an embodiment. As shown, the liner 315 may be provided in direct contact with the glass layer 325. That is, the liner 315 separates the buffer layer 337 from the glass layer 325. The liner 315 may have a thickness that is between approximately 1 μm and approximately 20 μm. Though, thinner or thicker liners 315 may be used in some embodiments.

In an embodiment, the via 335 is in direct contact with the buffer layer 337. The via 335 and the buffer layer 337 may form a seam or interface 338 that is visible in some instances. The interface 338 may be substantially similar to the interface 138 described in greater detail above. In an embodiment, the buffer layer 337 may include voids 341 or the like.

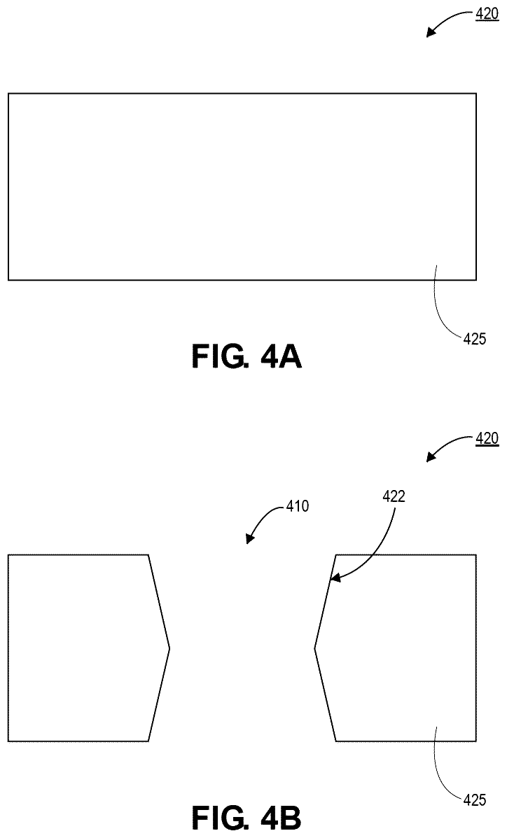

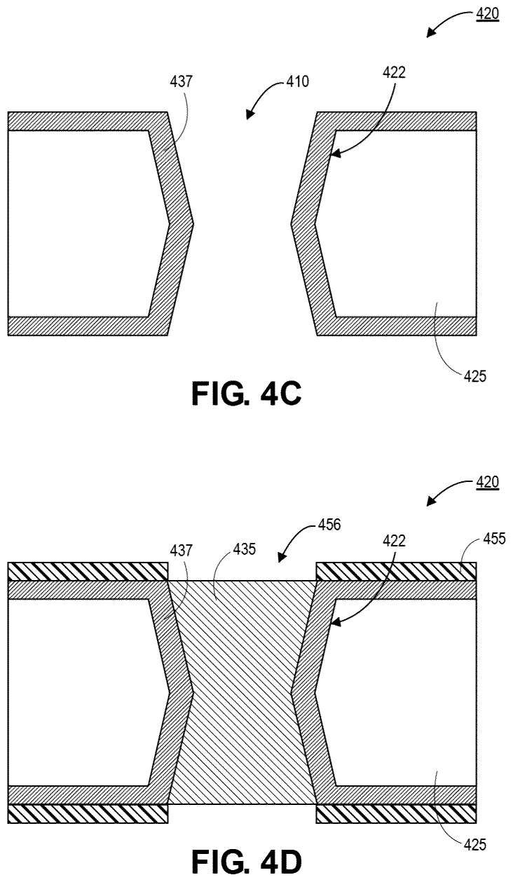

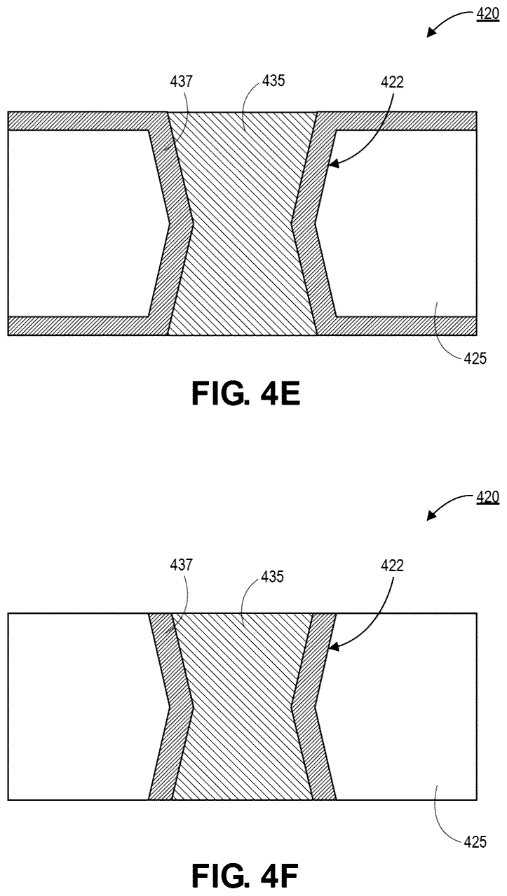

Referring now to FIGS. 4A-4F, a series of cross-sectional illustrations depicting a process for forming a glass core 420 with a via structure is shown, in accordance with an embodiment. The processing described in FIGS. 4A-4F includes the use of CVD or PVD processes in order to form a porous buffer layer 437. The glass core 420 in FIGS. 4A-4F may be similar to the structure described in greater detail above with respect to FIG. 1A.

Referring now to FIG. 4A, a cross-sectional illustration of a glass core 420 is shown, in accordance with an embodiment. In an embodiment, the glass core 420 comprises a glass layer 425. The glass layer 425 may be similar in composition and shape as other glass layers described in greater detail herein.

Referring now to FIG. 4B, a cross-sectional illustration of the glass core 420 after a via opening 410 is formed through a thickness of the glass core 425 is shown, in accordance with an embodiment. In an embodiment, the via opening 410 is formed with a laser assisted etching process. Such a process may include exposing the glass core 425 to a laser. The laser modifies the microstructure of the glass core 425 and renders the exposed area more susceptible to an etching process. In an embodiment, the via opening 410 is formed with a dual sided laser exposure approach. As such, sidewalls 422 of the via opening 410 will have a double taper structure. That is, the via opening 410 may have an hourglass shaped cross-section. Though, single sided laser exposure approaches may also be used in some embodiments.

Referring now to FIG. 4C, a cross-sectional illustration of the glass core 420 after the buffer layer 437 is applied is shown, in accordance with an embodiment. In an embodiment, the buffer layer 437 may be an electrically conductive layer (e.g., comprising copper) that has a relatively high porosity. For example, a porosity of the buffer layer 437 may be up to approximately 60% in some embodiments. The high porosity of the buffer layer 437 may result in the buffer layer 437 having a lower elastic modulus compared to nonporous copper. The buffer layer 437 may have a thickness between approximately 5 μm and approximately 20 μm in some embodiments. As shown, the buffer layer 437 may be deposited along sidewalls 422 of the via opening 410 and over the top and bottom surfaces of the glass layer 425.

In an embodiment, the buffer layer 437 may be deposited with a CVD or PVD process. Such processes allow for the deposition of the buffer layer 437 directly onto the surface of the glass layer 425. That is, a seed layer is not needed in the embodiment shown in FIG. 4C. In an embodiment, the parameters of the CVD or PVD process can be tuned in order to provide a desired porosity for the buffer layer 437.

Referring now to FIG. 4D, a cross-sectional illustration of the glass core 420 after the via 435 is deposited is shown, in accordance with an embodiment. In an embodiment, the via 435 comprises copper, a copper alloy, or another electrically conductive material. In an embodiment, the via 435 and the buffer layer 437 comprise the same (or substantially the same) material composition. In an embodiment, the via 435 may be deposited with a plating process, such as an electroplating process. The underlying buffer layer 437 can be used to initiate the plating process. As such, the via 435 may be provided directly on the buffer layer 437. The via 435 may have a porosity that is less than the porosity of the buffer layer 437. For example, the via 435 may be substantially nonporous, or the via 435 may have a porosity up to approximately 10%. In an embodiment, a resist layer 455 (e.g., a dry film resist) may be provided over the top and bottom surfaces of the glass layer 425. An opening 456 through the resist layer 455 allows for plating of the via only within the via 435 opening 410.

Referring now to FIG. 4E, a cross-sectional illustration of the glass core 420 after the resist layer 455 is removed is shown, in accordance with an embodiment. The resist layer 455 may be removed with a resist stripping process or the like. Accordingly, the portions of the buffer layer 437 over and under the glass layer 425 are exposed.

Referring now to FIG. 4F, a cross-sectional illustration of the glass core 420 after the excess portions of the buffer layer 437 are removed is shown, in accordance with an embodiment. In an embodiment, the excess portions of the buffer layer 437 over the glass layer 425 may be removed with an etching process, such as a timed wet etch. Though, in other embodiments, a planarization process (e.g., chemical mechanical planarization (CMP)) may be used to remove the excess copper.

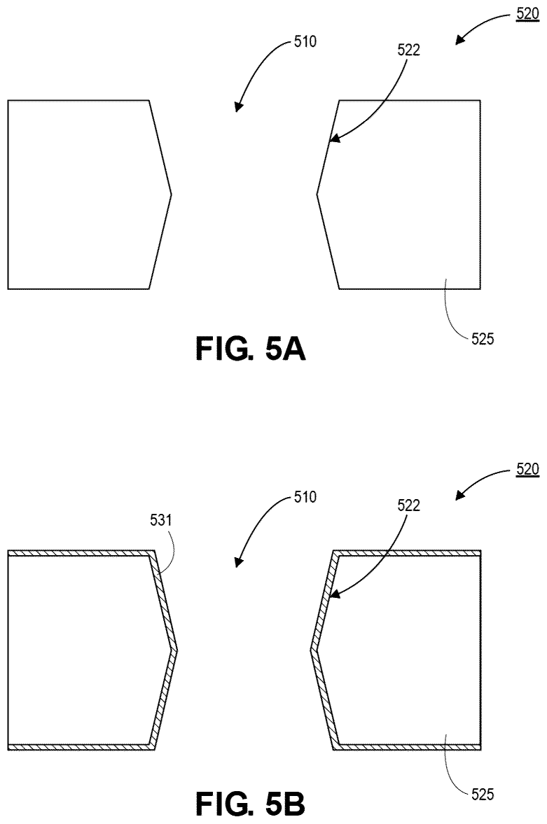

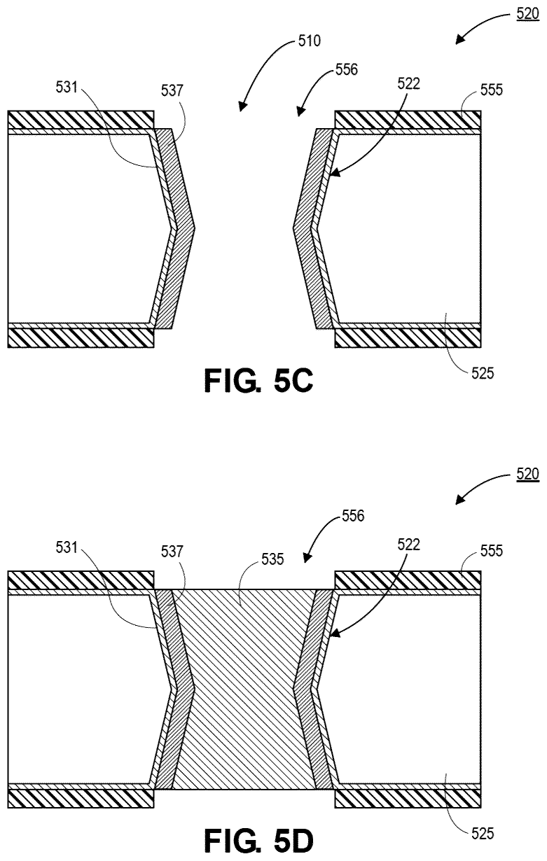

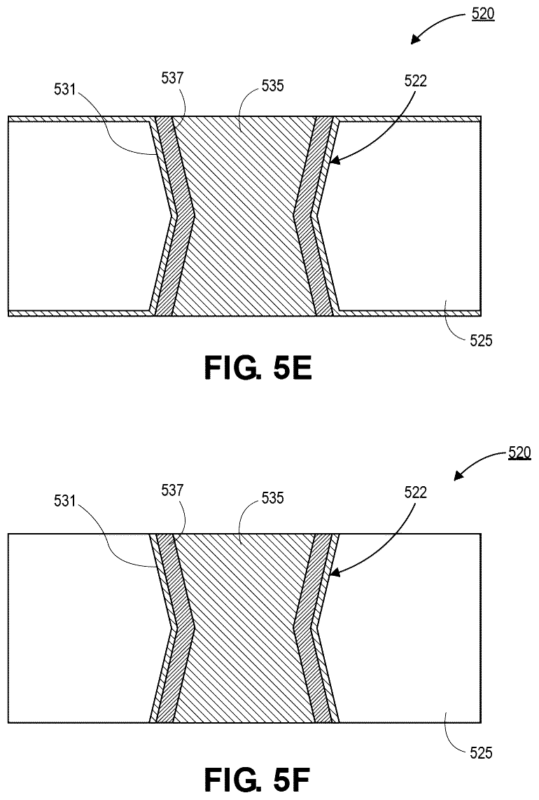

Referring now to FIGS. 5A-5F, a series of cross-sectional illustrations depicting a process for forming a glass core 520 with a via structure is shown, in accordance with an embodiment. The processing described in FIGS. 5A-5F includes the use of an electroplating process in order to form a porous buffer layer 537. The glass core 520 in FIGS. 5A-5F may be similar to the structure described in greater detail above with respect to FIG. 2A.

Referring now to FIG. 5A, a cross-sectional illustration of a glass core 520 is shown, in accordance with an embodiment. In an embodiment, the glass core 520 may comprise a glass layer 525. The glass layer 525 may be similar to any of the glass layers described in greater detail herein. In an embodiment, a via opening 510 is formed through a thickness of the glass layer 525. Sidewalls 522 of the via opening 510 may have a double tapered profile as a result of a laser assisted etching process. Though, it is to be appreciated that the cross-sectional shape of the via opening 510 may be any shape, depending on the processing used to form the via opening 510.

Referring now to FIG. 5B, a cross-sectional illustration of the glass core 520 after a seed layer 531 is disposed over surfaces of the glass layer 525 is shown, in accordance with an embodiment. In an embodiment, the seed layer 531 may be formed over the glass layer 525 with any suitable process, electroless plating, vapor deposition, atomic layer deposition, or the like. The seed layer 531 may comprise copper. Additionally, catalyst elements (such as palladium) may also be included in the seed layer 525.

Referring now to FIG. 5C, a cross-sectional illustration of the glass core 520 after a buffer layer 537 is deposited is shown, in accordance with an embodiment. In an embodiment, the buffer layer 537 may comprise a porous electrically conductive material. For example, the buffer layer 537 may be a porous copper layer. The porosity of the buffer layer 537 may be up to approximately 60% in some embodiments. The buffer layer 537 is selectively deposited along the sidewalls 522 of the via opening 510 through the use of a resist layer 555 over the top and bottom surface of the glass layer 525. An opening 556 in the resist layer 555 is provided around the via opening 510.

In an embodiment, the buffer layer 537 is plated up from the seed layer 531 with an electroplating process. In order to provide a high porosity layer, the buffer layer 537 may be plated with a high current density. For example, current densities of up to approximately 5 A/cm² may be used. In a particular embodiment, the current density used to plate the buffer layer 537 may be between approximately 0.1 A/cm² and approximately 10 A/cm².

Referring now to FIG. 5D, a cross-sectional illustration of the glass core 520 after the via 535 is formed is shown, in accordance with an embodiment. In an embodiment, the via 535 comprises copper, a copper alloy, or another electrically conductive material. In an embodiment, the via 535 and the buffer layer 537 comprise the same (or substantially the same) material composition. In an embodiment, the via 535 may also be formed with an electroplating process. However, in order to provide a nonporous (or low porosity) via 535, the current density for the electroplating may be lower than that used to plate the buffer layer 537. In an embodiment, current densities up to approximately 1 A/cm² may be used to plate the via 535. For example, current densities between approximately 1 mA/cm² and approximately 100 mA/cm² may be used to plate the via 535.

Using an electroplating process for both the buffer layer 537 and the via 535 provides manufacturing simplicity. This is because the buffer layer 537 and the via 535 can be plated within the same plating bath. For example, plating may be initiated with a high current density to plate the buffer layer 537, and the plating may switch to a lower current density after the buffer layer 537 is completed in order to form a nonporous via 535.

Referring now to FIG. 5E, a cross-sectional illustration of the glass core 520 after the resist layer 555 is removed is shown, in accordance with an embodiment. The resist layer 555 may be removed with a resist stripping process or the like. Accordingly, the portions of the seed layer 531 over and under the glass layer 525 are exposed.

Referring now to FIG. 5F, a cross-sectional illustration of the glass core 520 after the excess portions of the seed layer 531 are removed is shown, in accordance with an embodiment. In an embodiment, the excess portions of the seed layer 531 over the glass layer 525 may be removed with an etching process, such as a timed wet etch. Though, in other embodiments, a planarization process (e.g., CMP) may be used to remove the excess copper.

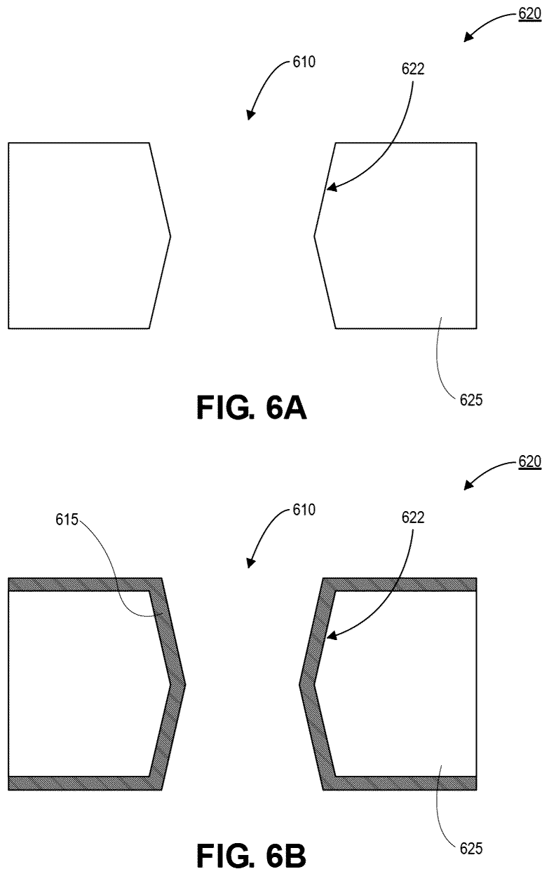

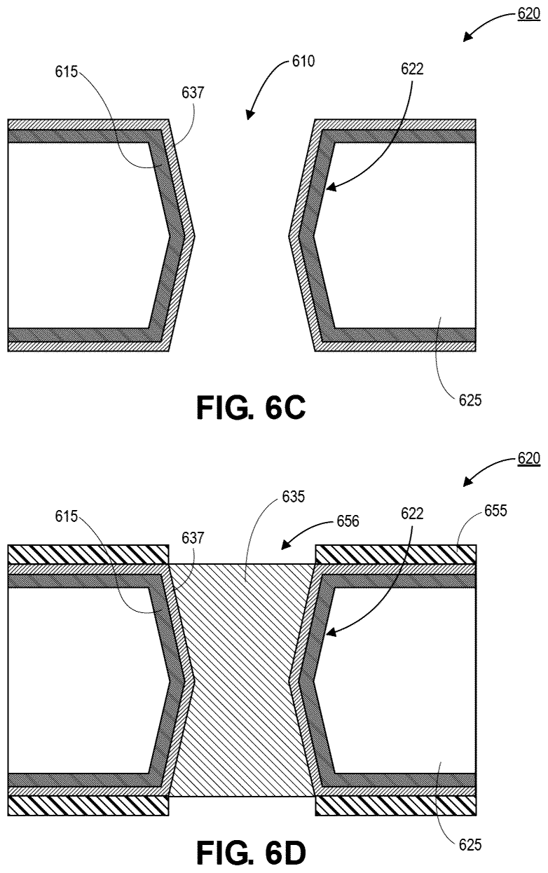

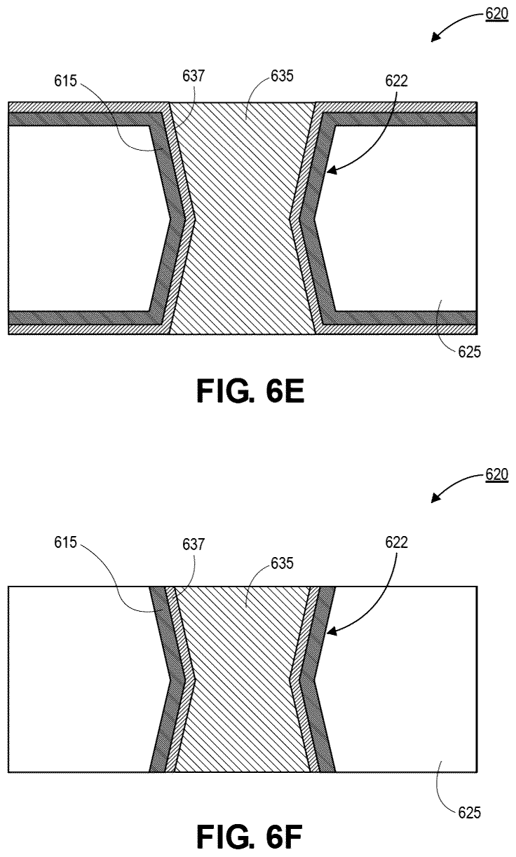

Referring now to FIGS. 6A-6F, a series of cross-sectional illustrations depicting a process for forming a glass core 620 with a via structure is shown, in accordance with an embodiment. The processing described in FIGS. 6A-6F includes the use of a liner between the buffer layer 637 and the glass layer 625. The glass core 620 in FIGS. 6A-6F may be similar to the structure described in greater detail above with respect to FIG. 3A.

Referring now to FIG. 6A, a cross-sectional illustration of a glass core 620 is shown, in accordance with an embodiment. In an embodiment, the glass core 620 may comprise a glass layer 625. The glass layer 625 may be similar to any of the glass layers described in greater detail herein. In an embodiment, a via opening 610 is formed through a thickness of the glass layer 625. Sidewalls 622 of the via opening 610 may have a double tapered profile as a result of a laser assisted etching process. Though, it is to be appreciated that the cross-sectional shape of the via opening 610 may be any shape, depending on the processing used to form the via opening 610.

Referring now to FIG. 6B, a cross-sectional illustration of the glass core 620 after a liner 615 is deposited is shown, in accordance with an embodiment. The liner 615 may be a low elastic modulus material. In some instances, the liner 615 may be electrically insulating. Though, electrically conductive liners 615 may also be used in some embodiments. The liner 615 may comprise a polymer, such as parylene. The liner 615 may be deposited with any suitable process, such as dip coating, spin coating, CVD, PVD, or the like. The liner 615 covers the sidewalls 622 of the via opening 610 and the top and bottom surfaces of the glass layer 625.

Referring now to FIG. 6C, a cross-sectional illustration of the glass core 620 after the buffer layer 637 is applied is shown, in accordance with an embodiment. The buffer layer 637 may be an electrically conductive and porous material. For example, the buffer layer 637 may comprise copper with up to approximately 60% porosity. The buffer layer 637 may be applied with a CVD or PVD process. In such instances, the buffer layer 637 is in direct contact with the liner 615. In other embodiments, a seed layer (not shown) may be provided over the liner 615 with an electroless process, and the buffer layer 637 may be plated with an electroplating process. The buffer layer 637 may be provided over the sidewalls 622 of the via opening 610 and over the top and bottom surfaces of the glass layer 625.

Referring now to FIG. 6D, a cross-sectional illustration of the glass core 620 after the via 635 is deposited is shown, in accordance with an embodiment. In an embodiment, the via 635 comprises copper, a copper alloy, or another electrically conductive material. In an embodiment, the via 635 and the buffer layer 637 comprise the same (or substantially the same) material composition. In an embodiment, the via 635 may be deposited with a plating process, such as an electroplating process. The underlying buffer layer 637 can be used to initiate the plating process. As such, the via 635 may be provided directly on the buffer layer 637. The via 635 may have a porosity that is less than the porosity of the buffer layer 637. For example, the via 635 may be substantially nonporous, or the via 635 may have a porosity up to approximately 10%. In an embodiment, a resist layer 655 (e.g., a dry film resist) may be provided over the top and bottom surfaces of the glass layer 625. An opening 656 through the resist layer 655 allows for plating of the via only within the via 635 opening 610.

Referring now to FIG. 6E, a cross-sectional illustration of the glass core 620 after the resist layer 655 is removed is shown, in accordance with an embodiment. The resist layer 655 may be removed with a resist stripping process or the like. Accordingly, the portions of the buffer layer 637 over and under the glass layer 625 are exposed.

Referring now to FIG. 6F, a cross-sectional illustration of the glass core 620 after the excess portions of the buffer layer 637 and liner 615 are removed is shown, in accordance with an embodiment. In an embodiment, the excess portions of the buffer layer 637 and the liner 615 over the glass layer 625 may be removed with an etching process, such as a timed wet etch. Though, in other embodiments, a planarization process (e.g., CMP) may be used to remove the excess copper and liner 615 material.

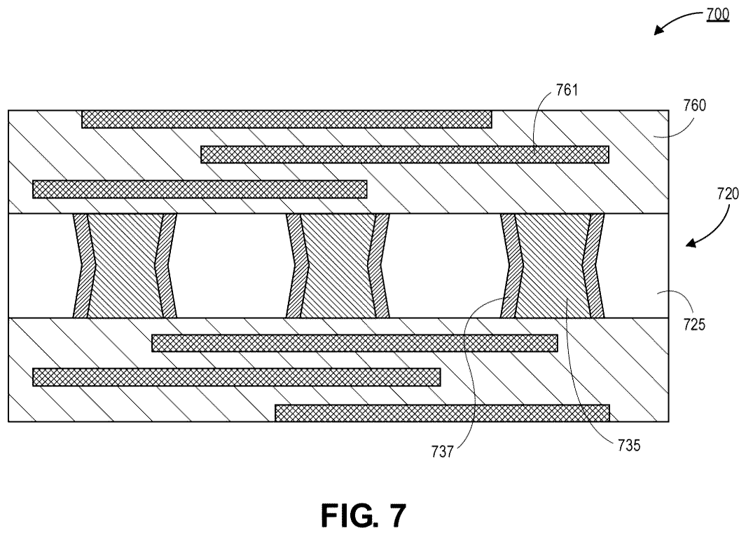

Referring now to FIG. 7, a cross-sectional illustration of a package substrate 700 is shown, in accordance with an embodiment. In an embodiment, the package substrate 700 comprises a glass core 720. The glass core 720 may include a glass layer 725 with via structures through a thickness of the glass core. In an embodiment, the via structures comprise a buffer layer 737 and a via 735. The buffer layer 737 and the via 735 may be the same material composition, but the two features may have different porosities. For example, the buffer layer 737 may have a porosity that is up to approximately 60% and the via 735 may have a porosity that is less than approximately 10%.

In an embodiment, the buffer layer 737 may be plated with an electroplating process. In such an embodiment, a seed layer (not shown) may be provided between the buffer layer 737 and the glass layer 725. In other embodiments, the buffer layer 737 may be deposited with a CVD or PVD process. In such embodiments, the buffer layer 737 may be in direct contact with the glass layer 725. Embodiments may also include a liner (not shown) between the buffer layer 737 and the glass layer 725. More generally, the via structure in FIG. 7 may be similar to any of the via structures described in greater detail herein.

In an embodiment, the package substrate 700 may further comprise buildup layers 760 above and/or below the glass core 720. The buildup layers 760 may comprise organic buildup material, such as buildup film. The buildup film may be laminated over each other in order to provide buildup layers 760 with a desired thickness. In an embodiment, electrically conductive features 761 (e.g., pads, traces, vias, etc.) may be embedded in the buildup layers 760.

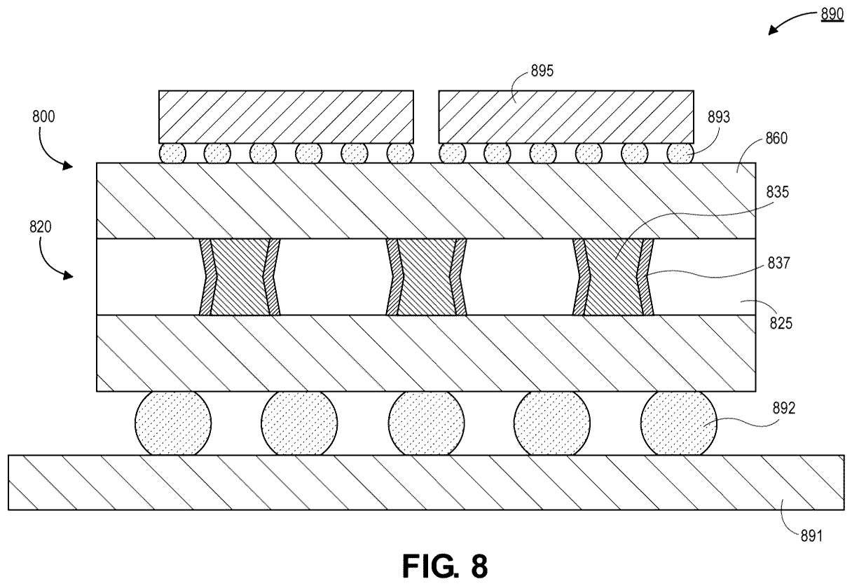

Referring now to FIG. 8, a cross-sectional illustration of an electronic system 890 is shown, in accordance with an embodiment. The electronic system 890 may comprise a board 891, such as a printed circuit board (PCB). In an embodiment, a package substrate 800 is coupled to the board 891 by interconnects 892. The interconnects 892 may be any suitable interconnect, such as second level interconnect (SLI) architectures. For example, interconnects 892 may comprise solder balls, sockets, or the like.

In an embodiment, the package substrate 800 in FIG. 8 may be similar to the package substrate 700 described above with respect to FIG. 7. For example, the package substrate 800 may comprise a glass core 820 with a glass layer 825. A via structure with a buffer layer 837 and a via 835 may be provided through a thickness of the glass layer 825. Buildup layers 860 may be provided above and/or below the glass core 820.

In an embodiment, one or more dies 895 may be coupled to the package substrate 800 by interconnects 893. The interconnects 893 may include first level interconnect (FLI) architectures. For example, the interconnects 893 may comprise solder bumps, copper bumps, hybrid bonding interfaces, or the like. The dies 895 may include any type of die. For example, the dies 895 may include a central processing unit (CPU), a graphics processing unit (GPU), an XPU, a communications die, a memory die, or the like. In some embodiments, two or more dies 895 may be communicatively coupled together by a bridge die (not shown) that is embedded within the buildup layers 860 of the package substrate 800 or provided over the buildup layers 860.

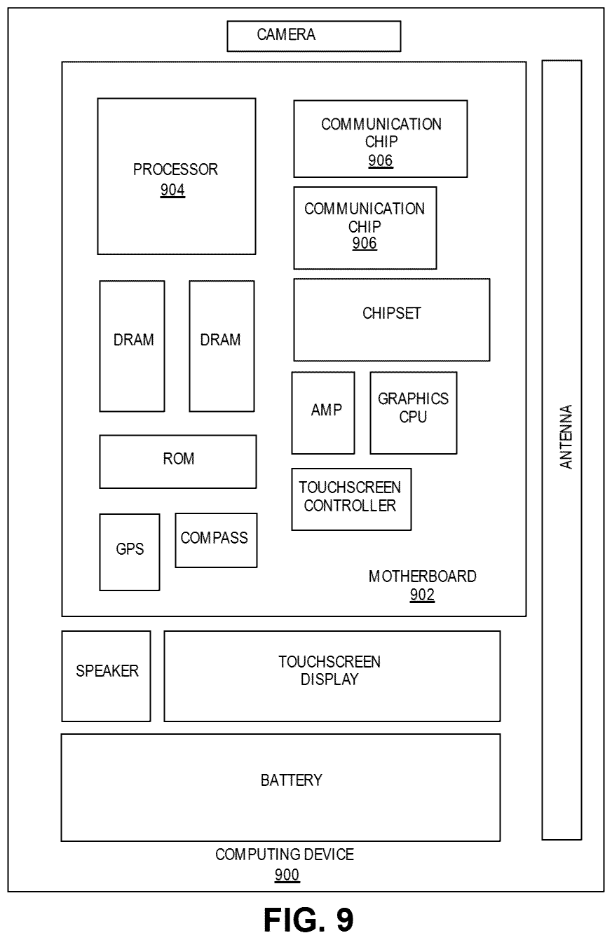

FIG. 9 illustrates a computing device 900 in accordance with one implementation of the disclosure. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the disclosure, the integrated circuit die of the processor may be part of an electronic package that includes a package substrate with a glass core that includes via structures that comprise a buffer layer with a high porosity and a via that is nonporous, in accordance with embodiments described herein. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the disclosure, the integrated circuit die of the communication chip may be part of an electronic package that includes a package substrate with a glass core that includes via structures that comprise a buffer layer with a high porosity and a via that is nonporous, in accordance with embodiments described herein.

In an embodiment, the computing device 900 may be part of any apparatus. For example, the computing device may be part of a personal computer, a server, a mobile device, a tablet, an automobile, or the like. That is, the computing device 900 is not limited to being used for any particular type of system, and the computing device 900 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate, wherein the substrate is a solid glass layer; an opening through a thickness of the substrate; and a via structure in the opening, wherein the via structure comprises: a first region, wherein the first region comprises an electrically conductive material with a first porosity; and a second region in contact with the first region, wherein the second region comprises an electrically conductive material with a second porosity that is less than the first porosity, and wherein the second region is separated from a sidewall of the opening by the first region.

Example 2: the apparatus of Example 1, wherein the first porosity is up to 60%, and wherein the second porosity is less than 10%.

Example 3: the apparatus of Example 2, wherein the second porosity is 0%.

Example 4: the apparatus of Examples 1-3, wherein the first region and the second region both comprise copper.

Example 5: the apparatus of Examples 1-4, wherein a thickness of the first region is up to approximately 20 μm.

Example 6: the apparatus of Examples 1-5, wherein the first region is in contact with the sidewall of the opening.

Example 7: the apparatus of Examples 1-6, further comprising: a liner between the first region and the sidewall of the opening.

Example 8: the apparatus of claim 7, wherein the liner comprises a polymer.

Example 9: the apparatus of Examples 1-8, further comprising: a seed layer between the first region and the sidewall of the opening, wherein the seed layer has a third porosity that is lower than the first porosity.

Example 10: the apparatus of Examples 1-9, wherein the sidewall of the opening has a sloped profile.

Example 11: an apparatus, comprising: a substrate, wherein the substrate is a solid glass layer; an opening through the substrate; a buffer layer over a sidewall of the opening, wherein the buffer layer is electrically conductive; and a via in the opening and surrounded by the buffer layer, wherein the via is electrically conductive, and wherein a visible seam is provided at an interface between the buffer layer and the via.

Example 12: the apparatus of Example 11, wherein the buffer layer has a porosity up to 60%.

Example 13: the apparatus of Example 11 or Example 12, wherein the seam is non-linear.

Example 14: the apparatus of Examples 11-13, wherein a thickness of the buffer layer is up to approximately 20 μm.

Example 15: the apparatus of Examples 11-14, wherein the buffer layer has a first elastic modulus and the via has a second elastic modulus that is higher than the first elastic modulus.

Example 16: the apparatus of Examples 11-15, wherein the buffer layer has a first electrical conductivity and the via has a second electrical conductivity that is higher than the first electrical conductivity.

Example 17: the apparatus of Examples 11-16, further comprising: a liner between the sidewall of the opening and the buffer layer, wherein the liner is electrically insulating.

Example 18: an apparatus, comprising: a board; a package substrate coupled to the board, wherein the package substrate comprises: a glass core; and a via structure through a thickness of the glass core, wherein the via structure comprises a ring with voids and a via within the ring, and wherein the via is nonporous; and a die coupled to the package substrate.

Example 19: the apparatus of Example 18, further comprising: an electrically insulating liner between the via and the glass core.

Example 20: the apparatus of Example 18 or Example 19, wherein the apparatus is part of a personal computer, a server, a mobile device, a tablet, or an automobile.

What is claimed is:

1. An apparatus, comprising:
a substrate, wherein the substrate is a solid glass layer;
an opening through a thickness of the substrate; and
a via structure in the opening, wherein the via structure comprises:
a first region, wherein the first region comprises an electrically conductive material with a first porosity; and
a second region in contact with the first region, wherein the second region comprises an electrically conductive material with a second porosity that is less than the first porosity, and wherein the second region is separated from a sidewall of the opening by the first region.

2. The apparatus of claim 1, wherein the first porosity is up to 60%, and wherein the second porosity is less than 10%.

3. The apparatus of claim 2, wherein the second porosity is 0%.

4. The apparatus of claim 1, wherein the first region and the second region both comprise copper.

5. The apparatus of claim 1, wherein a thickness of the first region is up to approximately 20 μm.

6. The apparatus of claim 1, wherein the first region is in contact with the sidewall of the opening.

7. The apparatus of claim 1, further comprising:
a liner between the first region and the sidewall of the opening.

8. The apparatus of claim 7, wherein the liner comprises a polymer.

9. The apparatus of claim 1, further comprising:
a seed layer between the first region and the sidewall of the opening, wherein the seed layer has a third porosity that is lower than the first porosity.

10. The apparatus of claim 1, wherein the sidewall of the opening has a sloped profile.

11. An apparatus, comprising:
a substrate, wherein the substrate is a solid glass layer;
an opening through the substrate;
a buffer layer over a sidewall of the opening, wherein the buffer layer is electrically conductive; and
a via in the opening and surrounded by the buffer layer, wherein the via is electrically conductive, and wherein a visible seam is provided at an interface between the buffer layer and the via.

12. The apparatus of claim 11, wherein the buffer layer has a porosity up to 60%.

13. The apparatus of claim 11, wherein the seam is non-linear.

14. The apparatus of claim 11, wherein a thickness of the buffer layer is up to approximately 20 μm.

15. The apparatus of claim 11, wherein the buffer layer has a first elastic modulus and the via has a second elastic modulus that is higher than the first elastic modulus.

16. The apparatus of claim 11, wherein the buffer layer has a first electrical conductivity and the via has a second electrical conductivity that is higher than the first electrical conductivity.

17. The apparatus of claim 11, further comprising:
a liner between the sidewall of the opening and the buffer layer, wherein the liner is electrically insulating.

18. An apparatus, comprising:
a board;
a package substrate coupled to the board, wherein the package substrate comprises:
a glass core; and
a via structure through a thickness of the glass core, wherein the via structure comprises a ring with voids and a via within the ring, and wherein the via is nonporous; and
a die coupled to the package substrate.

19. The apparatus of claim 18, further comprising:
an electrically insulating liner between the via and the glass core.

20. The apparatus of claim 18, wherein the apparatus is part of a personal computer, a server, a mobile device, a tablet, or an automobile.
